(19) United States
(12) Patent Application Publication
(10) Pub. No.: US 2012/0192932 A1
(43) Pub. Date: Aug. 2, 2012

(54) SOLAR CELL AND ITS ELECTRODE STRUCTURE

(75) Inventors: MENG-HSIU WU, Hsinchu (TW); YU-WEI TAI, Hsinchu (TW); WEI-MING CHEN, Hsinchu (TW); YANG-FANG CHEN, Hsinchu (TW)

(73) Assignee: NEO SOLAR POWER CORP., Hsinchu City (TW)

(21) Appl. No.: 13/441,867

(22) Filed: Apr. 7, 2012

Related U.S. Application Data
(63) Continuation-in-part of application No. 13/072,655, filed on Mar. 25, 2011.

(51) Int. Cl. H01L 31/0224

(52) U.S. Cl. 136/252

(57) ABSTRACT

An electrode structure is disposed on a substrate of a solar cell. The electrode structure includes a plurality of bus electrodes, a plurality of finger electrodes, and at least one connection electrode. The bus electrodes are separately disposed on the substrate. The finger electrodes are disposed on two sides of the bus electrodes and electrically connect to the bus electrodes. The connection electrode is disposed on a side of the substrate and connects with at least two finger electrodes. The connection electrode, bus electrodes and the finger electrodes are formed by at least two screen printing processes, and at least one of the screen printing processes does not form the bus electrodes. Thus, the thicknesses of the finger electrodes are greater than those of the bus electrodes.

### CROSS REFERENCE TO RELATED APPLICATIONS

This application is a Continuation-In-Part (CIP) of an earlier filed, copending U.S. Patent application, having U.S. application Ser. No. 13/072,655 and filed on Mar. 25, 2011, the content of which, including drawings, is expressly incorporated by reference herein.

### BACKGROUND OF THE INVENTION

1. Field of Invention

The present invention relates to an electrode structure and, in particular, to an electrode structure for a solar cell.

2. Related Art

The manufacture of silicon wafers is a very developed technology, and it is widely applied to the various semiconductor products. In addition, the energy gap of the silicon atoms is suitable for absorbing solar energy, so that the silicon solar cell has become the most popular solar cell. In generally, the structure of the single-crystal or poly-crystal silicon solar cell usually includes the following layers of: an external electrode, an anti-reflective layer, an N-type semiconductor layer, a P-type semiconductor layer, and a back contact electrode.

When the N-type semiconductor layer contacts with the P-type semiconductor layer, an internal electron field is thus generated. When the solar light reaches the P-N structure, the P-type semiconductor and the N-type semiconductor layer can absorb the energy of the solar light to generate the electron-hole pairs. Then, the internal electric fields in the depletion region can drive the generated electron-hole pairs to induce the electron flow inside the semiconductor layers. If the electrodes are properly applied to output the electrons, the solar cell can operate.

The external electrode is usually made of nickel, silver, aluminum, copper, palladium, and their combinations. In order to output sufficient amount of the electron flow, a large conductive surface between the electrodes and the substrate is needed. However, the surface area of the substrate covered by the external electrode should be as small as possible so as to decrease the obscuring rate of the solar light caused by the external electrode. Therefore, the design of the external electrode structure should satisfy both the properties of low resistance and low obscuring rate.

Accordingly, the external electrode structure usually includes the bus electrode and the finger electrode. The cross-sectional area of the bus electrode is larger than that of the finger electrode. The bus electrode is the main body, and the finger electrodes are branched from the bus electrode and distributed all over the surface of the solar cell. Thus, the electrons can be collected by the finger electrodes and then transmitted to the external load through the bus electrode. In other words, the bus electrode with larger dimension is help for increasing the electron flow, and the finger electrodes with smaller dimension are help for decreasing the light obscuring rate.

FIG. 1a is a schematic diagram of a conventional solar cell 1, and FIG. 1b is the top view of the electrode structure of the conventional solar cell 1. To be noted, FIG. 1a only shows one bus electrode for concise purpose. As shown in FIGS. 1a and 1b, a substrate 10 is constructed by a P-type semiconductor layer 101 and an N-type semiconductor layer 102. A bus electrode 111 and a plurality of finger electrodes 112 are formed by screen printing process on a surface of the substrate 10, which is used for receiving light. The bus electrode 111 and the finger electrodes 112 together form the electrode structure 11. The electrons are collected from the finger electrodes 112 to the bus electrode 111, and then the bus electrode 111 can output the electrons. An anti-reflective layer 12 is disposed on the surface of the substrate 10. The material of the anti-reflective layer 12 includes silicon nitride, so that the anti-reflective layer 12 can be transparent for decreasing the reflection so as to increase the photo-electro transition rate. In addition, the rear surface of the substrate 10 is covered by a back contact electrode 13, which is coupled to the electrode structure 11 for providing electricity to the external load or power storage.

In general, the electrode structure is formed by the screen printing process. By several times of screen printing, the bus electrodes and finger electrodes are simultaneously formed on the substrate with the same thickness. Compared with the bus electrodes with larger width, the finger electrodes have smaller width, so that their resistance is higher. This is an impediment to the transmission of the electron flow.

Therefore, it is an important subject of the present invention to provide an electrode structure of the solar cell that can reduce the resistance of the finger electrode so as to increase the conductivity and can still remain the low light obscuring rate so as to keep the efficiency of photo-electro transition.

### SUMMARY OF THE INVENTION

In view of the foregoing subject, an objective of the present invention is to provide an electrode structure of a solar cell that has reduced resistance low light obscuring rate so as to enhance the efficiency of photo-electro transition.

Another objective of the present invention is to provide an electrode structure of a solar cell, which is formed by multiple screen printing processes, wherein at least one of the screen printing processes does not form the bus electrodes. Thus, the manufacturing cost can be decreased.

To achieve the above objectives, the present invention discloses an electrode structure, which is disposed on a substrate of a solar cell. The electrode structure includes a plurality of bus electrodes, a plurality of finger electrodes, and at least one connection electrode. The bus electrodes are separately disposed on the substrate. The finger electrodes are disposed on two sides of the bus electrodes and electrically connected to the bus electrodes. The connection electrode is disposed on a side of the substrate and connects with at least two finger electrodes. The connection electrode, the bus electrodes and the finger electrodes are formed by at least two screen printing processes, and at least one of the screen printing processes does not form the bus electrodes.

To achieve the above objectives, the present invention also discloses a solar cell includes a substrate; and an electrode structure disposed on the substrate. The electrode structure includes a first screen printed layer and a second screen printed layer. The first screen printed layer is disposed on the substrate and defines bottom portions of a plurality of finger electrodes. The second screen printed layer is disposed on the first screen printed layer and defines top portions of the finger electrodes. One of the first and second screen printed layers defines a bus electrode, and the other one of the first and second screen printed layer does not define the bus electrode. At least one of the first and second screen printed layer defines at least one connection electrode being connected with at least two of the finger electrodes.

In one embodiment of the present invention, widths of the electrodes defined within the first and second screen printed layers are different.

In one embodiment of the present invention, only the second layer defines the bus electrodes, and the bus electrode is disposed on the substrate.

In one embodiment of the present invention, the connection electrode and the bus electrodes are respectively defined within the different one of the first and second screen printed layers.

In one embodiment of the present invention, the connection electrode and the bus electrodes are both defined within one of the first and second screen printed layers.

In one embodiment of the present invention, both of the first and second screen printed layer defines the connection electrode.

In one embodiment of the present invention, the dimension of one end (e.g. a first end) of the finger electrode contact with the bus electrode is larger than the dimension of the other end (e.g. a second end) of the finger electrode away from the bus electrode. Each finger electrode has a taper shape with the first end larger than the second end, so that it has a trapezoid shape for example.

In one embodiment of the present invention, the finger electrodes are formed by at least two screen printing processes to form the same or different patterns, shapes or dimensions.

The electronic property of the solar cell is sufficiently related to the light utility and the electron transmission resistance. In the prior art, the external electrode is formed on the substrate of the solar cell by screen printing processes, and it includes a plurality of bus electrodes and a plurality of finger electrodes. The material of the external electrode usually includes silver or silver-aluminum slurry, which is then sintered by high temperature. The formed external electrode can collect the electron flow after the photo-electro transition. However, a single screen printing process can not perfectly form the external electrode with the desired height. That is because the printed silver or silver-aluminum slurry is not solid before the high-temperature sintering. If the printed silver or silver-aluminum slurry is too high or their surface area is too large, the lower liquid slurry can not support the upper slurry. Thus, the upper slurry may flow toward two sides, and the desired pattern (e.g. the rectangular net distribution) for reducing the contact area with the substrate and lowering the light obscuring rate can not be formed. Accordingly, multiple repeated screen printing and high-temperature sintering are needed to form the external electrode with the desired thickness.

As mentioned above, in the electrode structure of the solar cell of the present invention, the bus electrodes, the finger electrodes and the connection electrode are formed by at least two screen printing processes, and at least one of the screen printing processes does not form the bus electrodes. Thus, the relative thicknesses of the finger electrodes and the bus electrodes can be controlled. In this invention, the thickness of the finger electrodes is larger than that of the bus electrodes, so that the resistance of the finger electrodes can be decreased and the conductivity thereof can be increased. In addition, because at least one of the screen printing processes does not form the bus electrodes, the manufacturing cost of the electrode structure can be reduced. Compared with the prior art, the present invention modifies the screen printing processes so as to achieve the lower light obscuring rate and resistance, thereby efficiently increasing the photo-electro transition rate of the solar cell.

### BRIEF DESCRIPTION OF THE DRAWINGS

The invention will become more fully understood from the detailed description and accompanying drawings, which are given for illustration only, and thus are not limitative of the present invention, and wherein:

FIG. 1a is a schematic diagram of a conventional solar cell;

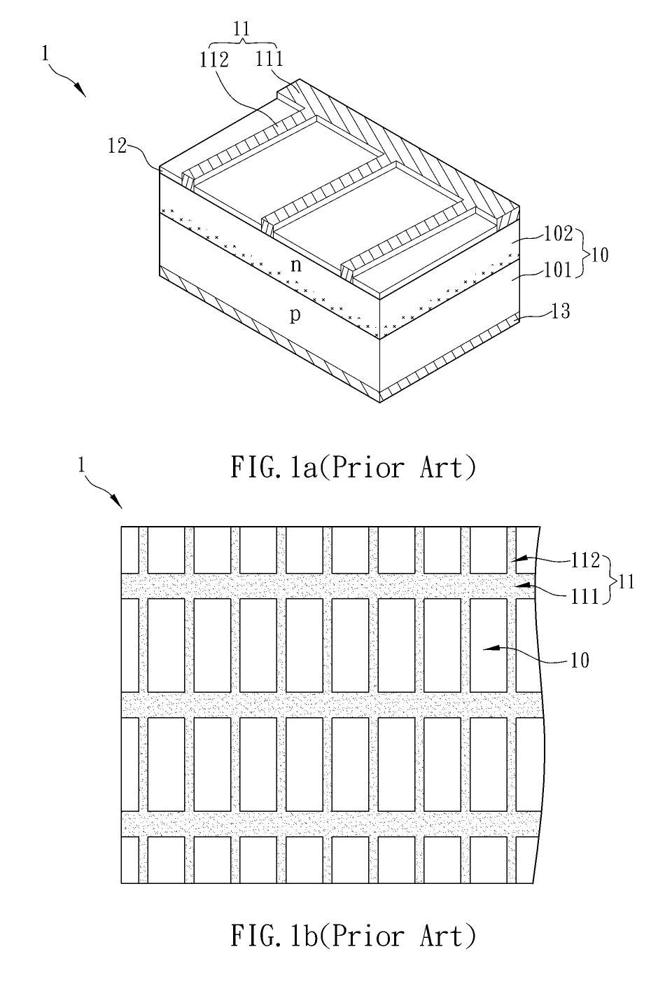

FIG. 1b is a top view of the electrode structure of the conventional solar cell;

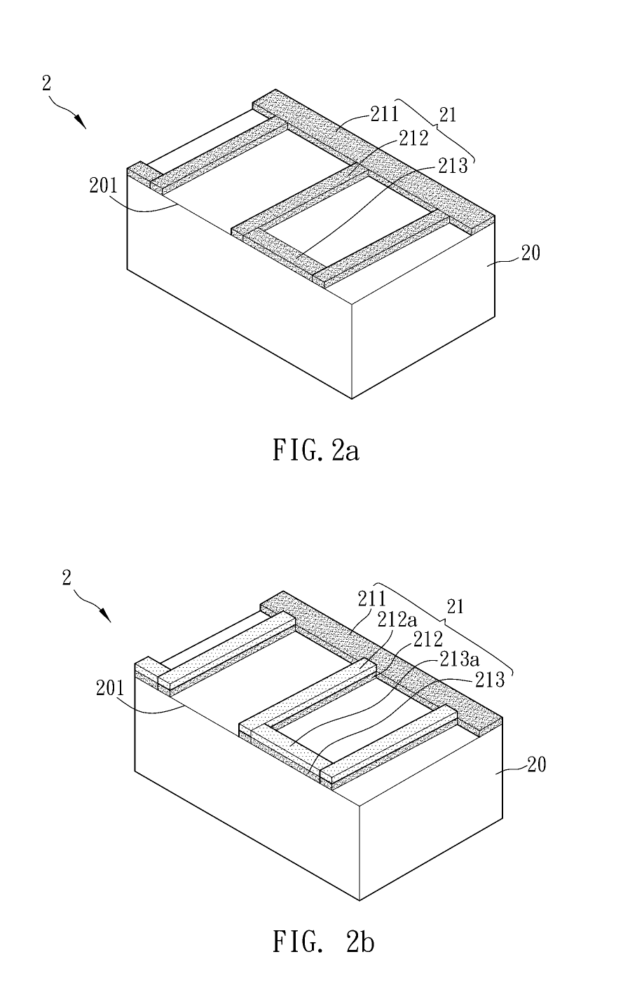

FIGS. 2a and 2b are schematic diagrams of an electrode structure of a solar cell according to an embodiment of the present invention;

FIGS. 3a and 3b are schematic diagrams showing two aspects of the electrode structure of the solar cell according to the embodiment of the present invention;

FIG. 4a and FIG. 4b are schematic diagrams of screen used in the screen printing of the present invention;

FIG. 5a is a top view of another electrode structure of the solar cell according to the embodiment of the present invention;

FIG. 5b is a schematic diagram showing various aspects of the finger electrode according to the embodiment of the present invention; and

FIG. 6 is a schematic diagram of another electrode structure of the solar cell according to the embodiment of the present invention.

### DETAILED DESCRIPTION OF THE INVENTION

The present invention will be apparent from the following detailed description, which proceeds with reference to the accompanying drawings, wherein the same references relate to the same elements.

A solar cell includes a substrate and an electrode structure disposed on the substrate. The electrode structure has a plurality of layers formed by at least two screen printing processes. These layers have a first screen printed layer by a first screen printing process and a second screen printed layer by a second screen printing process. The first screen printed layer is disposed on the substrate and defines bottom portions of a plurality of finger electrodes. After the first screen printing process form the first screen printed layer, the second screen printed layer is disposed on the first screen printed layer by the second screen printing process. The second printed layer defines top portions of the finger electrodes. Both first and second printed layer define parts of the finger electrodes. One of the first and second screen printed layers defines a bus electrode, and the other one of the first and second screen printed layer does not define the bus electrode. The bus electrode is formed by only one of the first and second screen printing processes. At least one of the first and second screen printed layer defines at least one connection electrode being connected with at least two of the finger electrodes. The connection electrode can be formed by one or both of the first and second screen printing processes. It is noted that the bus electrode can be formed within the first printed layer by the first screen printing process, or it can be formed within the second printed layer by the second screen printing process. Similarly, the connection electrode can be formed within the first printed layer by the first screen printing process, or it can be formed within the second printed layer by the second screen printing process.

For example, the first and second printed layers can be configured as several types. In one type, only the second layer defines the bus electrodes, and the bus electrode is disposed on the substrate. In other type, the connection electrode and the bus electrodes are respectively defined within the different one of the first and second screen printed layers. In another type, the connection electrode and the bus electrodes are both defined within one of the first and second screen printed layers. In another type, both of the first and second screen printed layer defines the connection electrode.

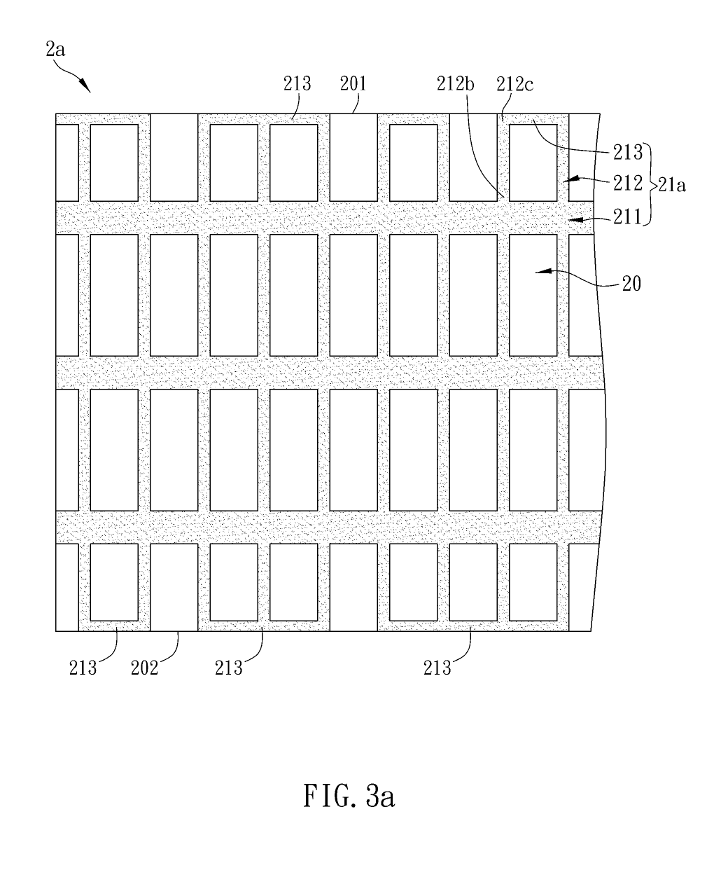

FIGS. 2a and 2b show an electrode structure 21 of a solar cell 2 according to an embodiment of the present invention, wherein only a bus electrode 211 is shown for concise purpose. The solar cell 2 of the embodiment can be a semiconductor solar cell or a thin-film solar cell. With reference to FIGS. 2a and 2b, an electrode structure 21 is disposed on a substrate 20 of a solar cell 2. The electrode structure 21 includes a plurality of bus electrodes 211, a plurality of finger electrodes 212, and at least one connection electrode 213. The bus electrodes 211 are separately disposed on the substrate 20. The finger electrodes 212 are disposed on two sides of the bus electrodes 211 and electrically connected to the bus electrodes 211. In more detailed, the bus electrodes 211 and the finger electrodes 212 are disposed on the light receiving surface of the substrate 20, and the bus electrodes 211 are substantially disposed in parallel. The width of the finger electrode 212 is smaller than that of any of the bus electrodes 211. In other words, the width of the bus electrode 211 is larger than that of the finger electrode 212, so that the resistance of the bus electrode 211 is obviously smaller than that of the finger electrode 212. The connection electrode 213 is disposed on a side 201 of the substrate 20 and connects with at least two finger electrodes 212 for enhancing the electrical connection of the finger electrodes 212. If a finger electrode 212 is broken into two separate parts due to the environment factor or external force, the electronic flows of the separate parts of the finger electrode 212 can still successfully reach the external load or storage element through different paths due to the connection electrode 213. This configuration can increase the photo-electro transition rate.

The bus electrodes 211 and the finger electrodes 212 are formed by at least two screen printing processes, and at least one of the screen printing processes does not form the bus electrodes 211. Accordingly, the relative thicknesses of the finger electrodes 212 and the bus electrodes 211 can be controlled. That is, the thickness of the finger electrode 212 is larger than that of the bus electrode 211, so that the resistance of the finger electrodes can be decreased.

The substrate 20 can be a semiconductor substrate, which is made of the semiconductor material with the photo-electro transition function such as the single-crystal silicon substrate, poly-crystal silicon substrate, or As—Ga substrate. In the embodiment, the substrate 20 includes at least one P-type semiconductor layer and at least one N-type semiconductor layer. In addition, an anti-reflective layer is disposed on the surface of the substrate 20 for decreasing the reflection, and a back contact electrode is disposed on the rear surface of the substrate 20 for conducting the solar cell to its load. These additional features are the same as the conventional semiconductor solar cell, so the detailed description thereof will be omitted. Besides, the substrate 20 can be a glass substrate, which includes at least one P-type semiconductor layer, at least one N-type semiconductor layer, and an anti-reflective layer. This feature is the same as the conventional thin-film solar cell, so the detailed description thereof will be omitted.

In order to conduct the electron flow, the bus electrodes 211, the finger electrodes 212 and the connection electrode 213 are usually made of metal. The material of the electrode structure 21 usually includes at least one of silver, tin, and their compounds. Of course, the electrode structure 21 can be made of other conductive materials, and it is not limited in this invention. In addition, the shape, amount and material of the bus electrodes 211, the finger electrodes 212 and the connection electrode 213 can be selectable depending on the dimension of the substrate 20 and any requirement, and it is also not limited in this invention.

For example, the bus electrodes 211, the finger electrodes 212 and the connection electrode 213 can be formed by screen printing processes, and they are disposed on the light receiving surface of the substrate 20 to form the electrode structure 21. The screen printing process includes at least two steps. In the embodiment, the first step is to print the bus electrodes 211, the finger electrodes 212 and the connection electrode 213 on the substrate 20, and cure the printed bus electrodes 211, finger electrodes 212 and the connection electrode 213. The second step is to only print the finger electrodes 212a on the substrate 20 and the connection electrode 213a so as to thicken the finger electrodes, and then cure the printed finger electrodes 212a and the connection electrode 213a. Accordingly, the thickness of the finger electrodes (212+212a) is larger than that of the bus electrode 211. In this embodiment, the width of the connection electrode 213/213a is roughly equal to that of the finger electrode 212/212a. However, this invention is not limited to this, and for example, the width of the connection electrode 213/213a may be different from that of the finger electrode 212/212a with a difference of about 50%. In details, the width of the connection electrode 213/213a may be larger or smaller than that of the finger electrode 212/212a. The connection electrode 213 connects the finger electrodes 212, and the connection electrode 213a connects the finger electrodes 212a.

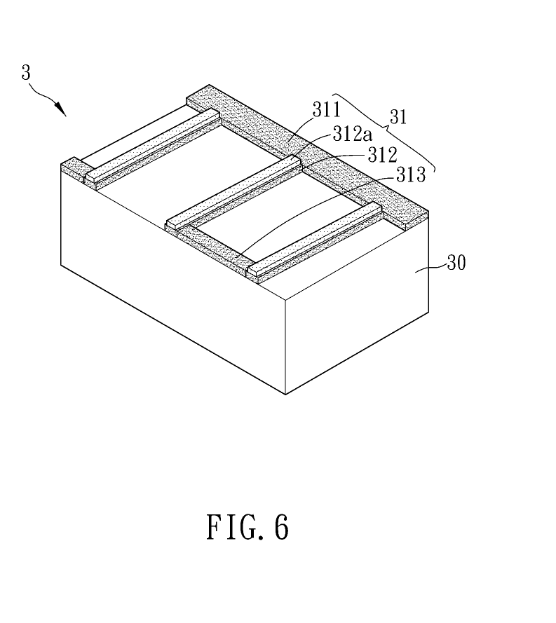

To be noted, the width of the finger electrodes 212a may be equal to that of the finger electrodes 212 (see FIG. 2b), or be smaller than that of the finger electrodes 212 (see FIG. 6). The finger electrodes formed by two screen printing processes may have the same or different patterns, shapes or dimensions. In this embodiment, the widths of the connection electrodes 213 and 213a are the same. Of course, in other embodiments, the widths of the connection electrodes 213 and 213a may be different. For example, the width of the connection electrode 213a may be smaller than that of the connection electrode 213; otherwise, the width of the connection electrode 213a may be larger than that of the connection electrode 213. In this embodiment, the electrode structure 21 can be formed by two screen printing processes. In practice, the connection electrodes 213 and 213a are respectively formed on the substrate 20 by two separate screen printing processes. Alternatively, it is also possible to form the connection electrodes on the substrate to connect the finger electrodes by only the first screen printing process (see FIG. 6), or to form the connection electrodes on the substrate by only the second screen printing process.

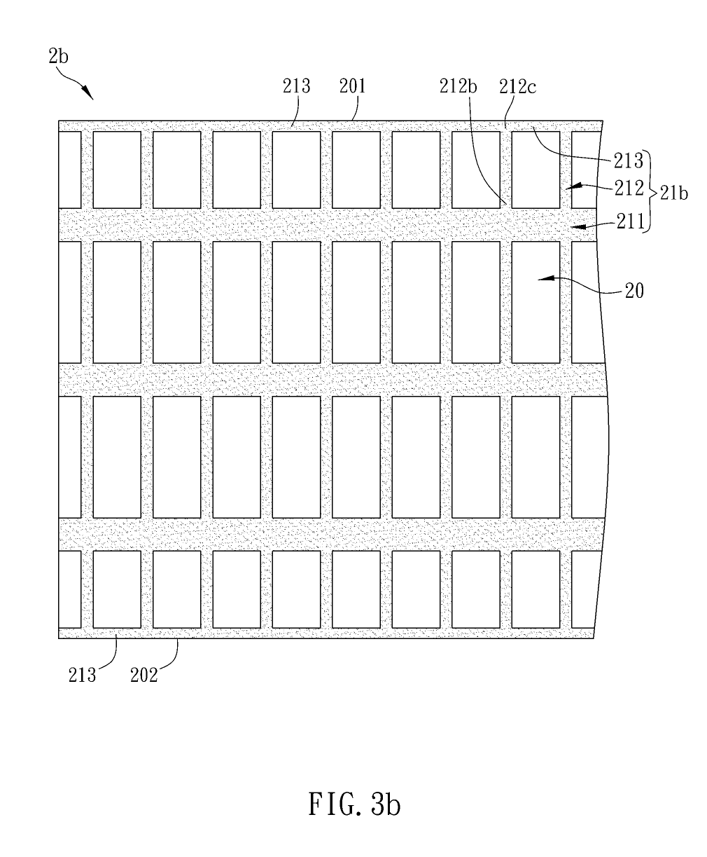

FIGS. 3a and 3b are schematic diagrams showing two aspects of the electrode structure of the solar cell according to the embodiment of the present invention. Referring to FIG. 3a, the electrode structure 21a of a solar cell 2a includes a plurality of connection electrodes 213, which are disposed at two sides 201 and 202 of the substrate 20. The connection electrodes 213 connect at least two finger electrodes 212. In practice, one connection electrode 213 may connect two, three, four or more finger electrodes 212. Referring to FIG. 3b, the electrode structure 21b of a solar cell 2b includes two connection electrodes 213, which are disposed at two sides 201 and 202 of the substrate 20, respectively. The connection electrodes 213 respectively connect the finger electrodes 212 disposed at two sides 201 and 202.

With reference to FIGS. 3a and 3b, the bus electrodes 211, the finger electrodes 212 and the connection electrode 213 are formed by two screen printing processes. For example, the first screen printing process can form the bottom portions of a plurality of finger electrodes 212 on the substrate 20, and then the second screen printing process can form a plurality of bus electrodes 211, a plurality of connection electrodes 213, and the top portions of the finger electrodes 212 on the substrate 20. Alternatively, the first screen printing process can form a plurality of connection electrodes 213 and the bottom portions of a plurality of finger electrodes 212, and then the second screen printing process can form a plurality of bus electrodes 211 and the top portions of the finger electrodes 212. In this case, the bus electrodes 211 and the connection electrodes 213 can be separately formed by the first and second screen printing processes; otherwise, they can be formed simultaneously by either the first screen printing process or the second screen printing process.

The steps for manufacturing the electrode structure 21 will be described hereinafter. Wherein, the first screen printing process forms the bottom portions of a plurality of finger electrodes 212 on the substrate 20, and the second screen printing process forms a plurality of bus electrodes 211, a plurality of connection electrodes 213, and the top portions of the finger electrodes 212 on the substrate 20 and the bottom portions of the finger electrodes 212, respectively.

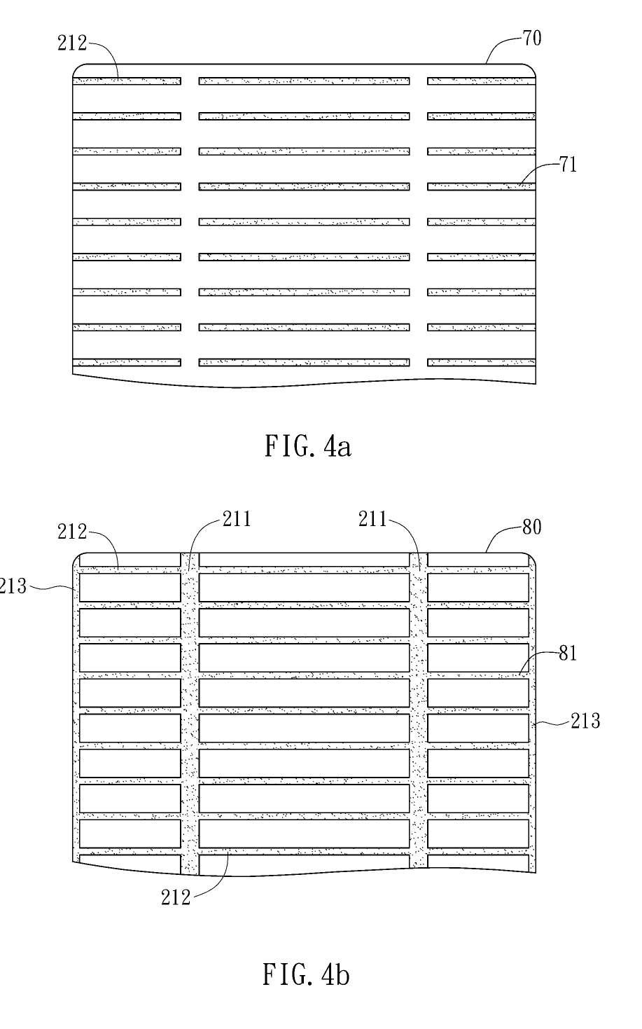

The screen of FIG. 4a and 4b can be used in different screen printing processes. For example, the screen of FIG. 4a and 4b can be respectively used in the first and second screen printing processes, or the screen of FIG. 4a and 4b can be respectively used in the second and first screen printing processes.

For example, the pattern of screen for widths of the electrodes can be different, such that the electrodes defined within the first and second screen printed layers are different.

In the embodiment, the screen of FIG. 4a and 4b are respectively used in the first and second screen printing processes for the structure in FIG. 3a. In the first screen printing process, a conductive material is separately disposed on the substrate 20 to form the bottom portions of a plurality of finger electrodes 212. FIG. 4a is a schematic diagram showing the screen 70. In this case, the screen 70 is used in the first screen printing process. During the first screen printing process, the applied material can be formed on the substrate 20 through the separate areas 71, thereby forming the bottom portions of the finger electrodes 212.

The bottom portions of the finger electrodes 212 are cured after the first screen printing process. In general, this curing step can remove the volatile solvent in the printed materials. This curing step can be carried out by thermal curing method or light curing method, for example, by UV light. In this embodiment, this curing step uses the thermal curing method to cure the bottom portions of the finger electrodes 212. In more detailed, after the first screen printing process, the substrate 20 is baked at 50-500° C. so as to remove the solvent without damaging the printed pattern.

Then, the second screen printing process is performed to separately dispose a conductive material on the substrate 20 to form a plurality of bus electrodes 211, a plurality of connection electrodes 213 and the top portions of the finger electrodes 212. FIG. 3b is a schematic diagram showing the screen 80. In this case, screen 80 is used in the second screen printing process. During the second screen printing process, the applied material can be formed on the substrate 20 through the separate areas 81, thereby forming the bus electrodes 211, the connection electrodes 213 and the top portions of the finger electrodes 212. Preferably, the material used in the first screen printing process is different from that used in the second screen printing process. For example, the materials used in the first and second screen printing processes may have different conductivities, and they may have different penetrabilities. Preferably, the conductivity of the material used in the second screen printing process is larger than that of the material used in the first screen printing process. Preferably, the penetrability of the material used in the first screen printing process is larger than that of the material used in the second screen printing process.

After the second screen printing process, the bus electrodes 211, the connection electrodes 213 and the top portions of the finger electrodes 212. In general, this curing step can remove the volatile solvent in the printed materials. This curing step can be carried out by thermal curing method or light curing method, for example, by UV light. In this embodiment, the curing method of this step is the same as that of the previous curing step for curing the bottom portions of the finger electrodes 212.

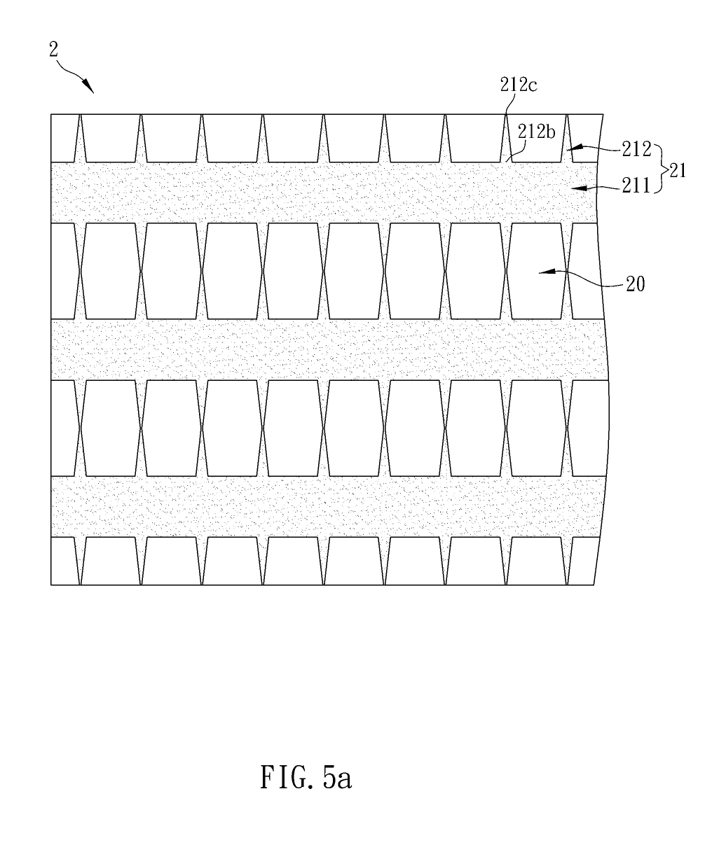

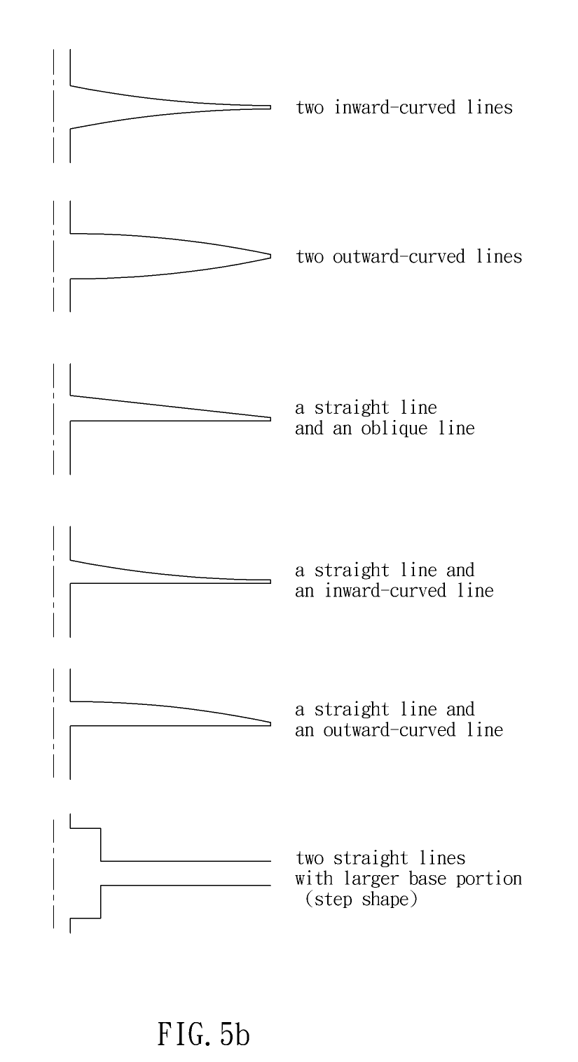

FIG. 5a is a top view of another electrode structure of the solar cell according to the embodiment of the present invention, wherein the bus electrodes 211 are substantially disposed in parallel.

In this embodiment, the finger electrodes 212 have a trapezoid shape. In more detailed, each finger electrode 212 has a first end 212b and a second end 212c, and the dimension of the first end 212b is larger than that of the second end 212c. The first end 212b of the finger electrode 212 contacts with one of the bus electrodes 211. Thus, the finger electrode 212 is tapered from the first end 212b to the second end 212c. The second ends 212c of the finger electrodes 212 between two adjacent bus electrodes 211 are connected with each other correspondingly. The bus electrodes 211 and the finger electrodes 212 are substantially perpendicular to each other. The finger electrodes 212 shown in FIG. 3a are for illustration only and are not to limit the scope of the present invention. For example, in the present embodiment, the width of the bus electrode 211 is about 2 mm, the first end 212b of the corresponding finger electrodes 212 has a dimension between 20 μm and 150 μm, and the second end 212c thereof has a dimension between 5 μm and 145 μm. The difference between the first end 212b and the second end 212c is between 5 μm and 70 μm. This configuration can efficiently reduce the resistance of the finger electrodes 212.

FIG. 5b is a schematic diagram showing various aspects of the finger electrode 212 according to the embodiment of the present invention. The aspects of the finger electrode 212 shown in FIG. 3b are only for illustration and are not to limit the scope of the present invention. As shown in FIG. 3b, the finger electrode 212 can be configured by any two of an inward-curved line, an outward-curved line, a straight line, and an oblique line. For example, the finger electrode 212 can be configured by two inward-curved lines, two outward-curved lines, a straight line and an oblique line, a straight line and an inward-curved line, or a straight line and an outward-curved line. Alternatively, the finger electrode 212 can have a step shape. The basic principle for designing the finger electrode is to make the dimension of the first end, which connects to the bus electrode, larger than that of the second end, which is far away from the bus electrode. Any design following this basic principle should be involved in the scope of the present invention.

FIG. 6 is a schematic diagram of another electrode structure of the solar cell according to the embodiment of the present invention. In this embodiment, the electrode structure 31 of a solar cell 3 can be manufactured by at least two screen printing processes. The first screen printing process is to form a plurality of bus electrodes 311, a plurality of finger electrodes 312 and a plurality of connection electrodes 313 on the substrate 30, and then the second screen printing process is to form a plurality of finger electrodes 312a on the finger electrodes 312. In this embodiment, the width of the finger electrodes 312a is, for example but not limited to, smaller than that of the finger electrodes 312.

To sum up, in the electrode structure of the solar cell of the present invention, the bus electrodes, the finger electrodes, and the connection electrodes are formed by at least two screen printing processes, and at least one of the screen printing processes does not form the bus electrodes. Thus, the thickness of the finger electrodes is larger than that of the bus electrodes. The present invention discloses a modified screen printing process to make the thickness of the narrower finger electrode to be larger than that of the wider bus electrode. This feature can decrease the resistance of the finger electrodes and still remain the light obscuring rate. In addition, because at least one of the screen printing processes does not form the bus electrodes, the manufacturing cost of the electrode structure can be reduced. Compared with the prior art, the present invention can achieve the lower light obscuring rate and resistance, thereby efficiently increasing the photo-electro transition rate of the solar cell.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. An electrode structure, which is disposed on a substrate of a solar cell, the electrode structure comprising:
a plurality of bus electrodes separately disposed on the substrate;
a plurality of finger electrodes disposed on two sides of the bus electrodes and electrically connected to the bus electrodes; and
at least a connection electrode disposed on a side of the substrate and connecting with at least two of the finger electrodes;
wherein the connection electrode, the bus electrodes and the finger electrodes are formed by at least two screen printing processes, and at least one of the screen printing processes does not form the bus electrodes.

2. The electrode structure of claim 1, wherein, a width of electrodes formed by one of the screen printing processes is different from a width of electrodes formed by the other one of the screen printing processes.

3. The electrode structure of claim 1, wherein each of the finger electrodes has a first end and a second end, the dimension of the first end is larger than that of the second end, and the first ends of the finger electrodes contact with one of the bus electrodes.

4. The electrode structure of claim 3, wherein the second ends of the finger electrodes located between adjacent two of the bus electrodes are connected to each other.

5. The electrode structure of claim 3, wherein the first end is between 20 μm and 150 μm, the second end is between 5 μm and 145 μm, and the difference between the first end and the second end is between 5 μm and 70 μm.

6. The electrode structure of claim 2, wherein each of the finger electrodes has a taper shape with the first end larger than the second end.

7. The electrode structure of claim 5, wherein the finger electrodes have a trapezoid shape.

8. The electrode structure of claim 1, wherein the width of the finger electrodes is smaller than that of any of the bus electrodes.

9. The electrode structure of claim 1, wherein the bus electrodes are substantially disposed in parallel, and the bus electrodes and the finger electrodes are substantially perpendicular to each other

10. The electrode structure of claim 1, wherein the finger electrodes are formed by at least two screen printing processes to form the same or different patterns, shapes or dimensions.

11. A solar cell, comprising:
a substrate; and
an electrode structure disposed on the substrate, comprising:
a first screen printed layer, which is disposed on the substrate and defines bottom portions of a plurality of finger electrodes; and
a second screen printed layer, which is disposed on the first screen printed layer and defines top portions of the finger electrodes;
wherein one of the first and second screen printed layers defines a bus electrode, and the other one of the first and second screen printed layer does not define the bus electrode;
wherein at least one of the first and second screen printed layer defines at least one connection electrode being connected with at least two of the finger electrodes.

12. The solar cell of claim 11, wherein widths of the electrodes defined within the first and second screen printed layers are different.

13. The solar cell of claim 11, wherein only the second layer defines the bus electrodes, and the bus electrode is disposed on the substrate.

14. The solar cell of claim 11, wherein the connection electrode and the bus electrodes are respectively defined within the different one of the first and second screen printed layers.

15. The solar cell of claim 12, wherein the connection electrode and the bus electrodes are both defined within one of the first and second screen printed layers.

16. The solar cell of claim 12, wherein both of the first and second screen printed layers define the connection electrode.
